(19) United States
(12) Patent Application Publication
(10) Pub. No.: US 2025/0372172 A1
(43) Pub. Date: Dec. 4, 2025

(54) STORAGE DEVICE AND METHOD OF OPERATING THE STORAGE DEVICE

(71) Applicant: SK hynix Inc., Icheon-si Gyeonggi-do (KR)

(72) Inventors: Jong Woo KIM, Icheon-si Gyeonggi-do (KR); Young Cheol SHIN, Icheon-si Gyeonggi-do (KR)

(73) Assignee: SK hynix Inc., Icheon-si Gyeonggi-do (KR)

(21) Appl. No.: 19/049,544

(22) Filed: Feb. 10, 2025

(30) Foreign Application Priority Data
Jun. 4, 2024 (KR) 10-2024-0073150

(51) Int. Cl. G11C 16/08; G11C 16/04; G11C 16/10

(52) U.S. Cl. CPC G11C 16/08; G11C 16/0483; G11C 16/102

(57) ABSTRACT

Provided herein is a memory device. The memory device includes a memory block, an operation processor, and an address allocator. The memory block includes a plurality of string groups connected to a plurality of word lines. The operation processor is configured to set a program operation mode of the memory block to one of a single-level cell (SLC) mode and a multi-level cell (MLC) mode in response to a command received externally from the memory device. The address allocator is configured to allocate a row address of the memory block differently depending on the program operation mode.

### CROSS-REFERENCE TO RELATED APPLICATION

The present application claims priority under 35 U.S.C. § 119(a) to Korean patent application number 10-2024-0073150 filed on Jun. 4, 2024, in the Korean Intellectual Property Office, the entire contents of which application is incorporated herein by reference.

### BACKGROUND

### 1. Technical Field

Various embodiments of the present disclosure generally relate to an electronic device, and more particularly to a storage device and a method of operating the storage device.

### 2. Related Art

A storage device is a device which stores data under the control of a host device, such as a computer or a smartphone. The storage device may include a memory device in which data is stored and a controller which controls the memory device. Memory devices are classified into a volatile memory device and a nonvolatile memory device.

The volatile memory device may be a memory device in which data is stored only when power is supplied and in which stored data is lost when the supply of power is interrupted. Examples of the volatile memory device may include a static random access memory (SRAM) and a dynamic random access memory (DRAM).

The nonvolatile memory device is a memory device in which stored data is retained even when the supply of power is interrupted. Examples of the nonvolatile memory device include a read only memory (ROM), a programmable ROM (PROM), an electrically programmable ROM (EPROM), an electrically erasable and programmable ROM (EEPROM), and a flash memory.

### SUMMARY

An embodiment of the present disclosure may provide for a memory device. The memory device may include a memory block, an operation processor, and an address allocator. The memory block may include a plurality of string groups connected to a plurality of word lines. The operation processor may be configured to set a program operation mode of the memory block to one of a single-level cell (SLC) mode and a multi-level cell (MLC) mode in response to a command received externally from the memory device. The address allocator may be configured to allocate a row address of the memory block differently depending on the program operation mode.

An embodiment of the present disclosure may provide for a memory controller for controlling a memory device, the memory device including a memory block including a plurality of string groups connected to a plurality of word lines. The memory controller may include a program scheduler and a command controller. The program scheduler may be configured to set a program operation mode of the memory block to one of a single-level cell (SLC) mode and a multi-level cell (MLC) mode and set a program order based on a row address of the memory block differently depending on the program operation mode. The command controller may be configured to provide a command indicating the program operation mode and the row address of the memory block depending on the program order to the memory device.

An embodiment of the present disclosure may provide for a storage device that includes a memory device including a memory block and a memory controller. A method of operating the storage device may include setting a program operation mode of the memory block to a single-level cell (SLC) mode in which 1 bit is stored per unit memory cell or a multi-level cell (MLC) mode in which 2 or more bits are stored per unit memory cell, and performing a program operation on the memory block on a string group basis in the SLC mode and performing the program operation on a word line basis in the MLC mode. The memory block may include a plurality of string groups connected to a plurality of word lines. A row address of the memory block may be determined depending on positions of the plurality of word lines and positions of the plurality of string groups.

### BRIEF DESCRIPTION OF THE DRAWINGS

FIG. 1 is a diagram illustrating a storage device according to an embodiment.

FIG. 2 is a diagram illustrating a memory device of FIG. 1 according to an embodiment.

FIG. 3 is a diagram illustrating the structure of a memory block of FIG. 2 according to an embodiment.

FIG. 4 is a diagram illustrating a partial structure of the memory block of FIG. 3 according to an embodiment.

FIG. 5 is a diagram illustrating a threshold voltage distribution depending on the number of data bits stored in each memory cell according to an embodiment.

FIG. 6 is a diagram illustrating the storage device of FIG. 1 according to an embodiment.

FIG. 7 is a diagram illustrating allocation of row addresses of a memory block by the memory device of FIG. 6 depending on a program operation mode according to an embodiment.

FIG. 8 is a diagram illustrating the storage device of FIG. 1 according to an embodiment.

FIG. 9 is a diagram illustrating the setting of a program order based on the row addresses of a memory block by a memory controller of FIG. 8 depending on a program operation mode according to an embodiment.

FIG. 10 is a diagram illustrating a partial erase operation on a string group according to an embodiment.

FIG. 11 is a flowchart illustrating a method of operating a storage device according to an embodiment.

FIG. 12 is a flowchart illustrating in detail the method of operating the storage device illustrated in FIG. 11 according to an embodiment.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

Various embodiments of the present disclosure are directed to a storage device and a method of operating the storage device, which efficiently manage a storage space.

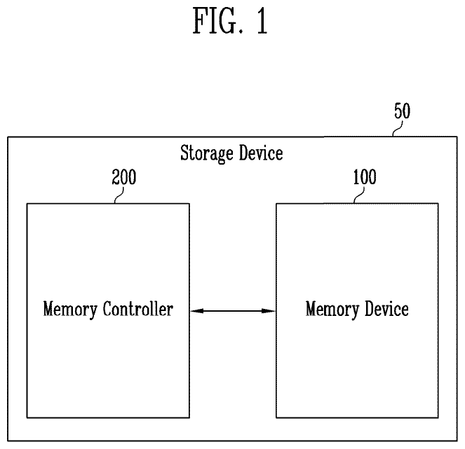

FIG. 1 is a diagram illustrating a storage device.

Referring to FIG. 1, a storage device 50 may include a memory device 100 and a memory controller 200. The storage device 50 may be a device which stores data under the control of a host, such as a mobile phone, a smartphone, a laptop computer, a desktop computer, a game console, a smart television (TV), a tablet PC, or an in-vehicle infotainment system. In an embodiment, the storage device 50 may be a device such as a server or a data center, controlled by the host, through wired/wireless communication for storing data at a remote place.

The storage device 50 may interface with the host in various communication schemes, and may be implemented using various devices depending on the interfacing scheme. For example, the storage device 50 may be implemented as any one of various types of storage devices, such as a solid state drive (SSD), an embedded multimedia card (eMMC), a SD, mini-SD, or micro-SD-type secure digital card, a universal serial bus (USB) storage device, a universal flash storage (UFS) device, a personal computer memory card international association (PCMCIA) card-type storage device, a peripheral component interconnection (PCI) card-type storage device, a PCI express (PCI-E) card-type storage device, a compact flash (CF) card, and a smart media card.

In an embodiment, the storage device 50 may be manufactured in any one of various types of package forms. For example, the storage device 50 may be manufactured in any one of various types of package forms, such as package on package (POP), system in package (SIP), system on chip (SOC), multi-chip package (MCP), chip on board (COB), wafer-level fabricated package (WFP), and wafer-level stack package (WSP).

The memory device 100 may store data. The memory device 100 may be operated in response to the control of the memory controller 200. The memory device 100 may include a plurality of memory cells which store data. Each of the memory cells may store one data bit or a plurality of data bits.

The memory cells may be accessed in units of a preset size depending on the type of memory device. The unit by which the memory cells are accessed may vary depending on each operation. For example, the memory cells may be accessed in units of different sizes for a write operation (program operation) of storing data in each memory cell, a read operation of measuring data stored in each memory cell, and an erase operation of erasing data stored in each memory cell.

In an embodiment, the memory device 100 may be a double data rate synchronous dynamic random access memory (DDR SDRAM), a low power double data rate fourth generation (LPDDR4) SDRAM, a graphics double data rate (GDDR) SDRAM, a low power DDR (LPDDR) SDRAM, a Rambus DRAM (RDRAM), a NAND flash memory, a vertical NAND flash memory, a NOR flash memory, a resistive RAM (RRAM), a phase-change memory (PCM), a magnetoresistive RAM (MRAM), a ferroelectric RAM (FRAM), or a spin transfer torque RAM (STT-RAM).

The memory device 100 may receive a command and an address from the memory controller 200, and may access the area of the memory cell array, selected by the address. The memory device 100 may perform an operation indicated by the command on the area selected by the address. For example, the memory device 100 may perform a write operation (program operation), a read operation, and an erase operation. During a program operation, the memory device 100 may write data to the area selected by the address. During a read operation, the memory device 100 may measure data from the area selected by the address. During an erase operation, the memory device 100 may erase data stored in the area selected by the address.

The memory controller 200 may control the overall operation of the storage device 50.

When power is applied to the storage device 50, the memory controller 200 may run firmware (FW). The storage device 50 may translate a logical block address (LBA), provided by the host, into a physical address (i.e., a physical block address: PBA) used by the memory device 100. The logical block address (LBA) may be an address for identifying data provided by the host. The physical address (PBA) may be an address indicating a position at which data is stored in the memory device 100. In the present specification, the logical block address (LBA) may have the same meaning as a logical address, and the physical block address (PBA) may have the same meaning as the physical address.

The memory controller 200 may control the memory device 100 to perform a write operation, a read operation or an erase operation in response to a request received from the host. During the write operation, the memory controller 200 may provide a write command (program command), an address, and data to the memory device 100. During the read operation, the memory controller 200 may provide a read command and an address to the memory device 100. During the erase operation, the memory controller 200 may provide an erase command and an address to the memory device 100.

In an embodiment, the memory device 100 may include a plurality of memory blocks, each of which may include a plurality of string groups connected to a plurality of word lines. Row addresses of the memory block may be determined depending on the positions of the plurality of word lines and the positions of the plurality of string groups.

In an embodiment, the memory controller 200 may set the program operation mode of the corresponding memory block to a single-level cell (SLC) mode in which 1 bit is stored per unit memory cell or a multi-level cell (MLC) mode in which 2 or more bits are stored per unit memory cell. The memory block may store 1 bit per unit memory cell in the SLC mode, and may store 2 or more bits per unit memory cell in the MLC mode.

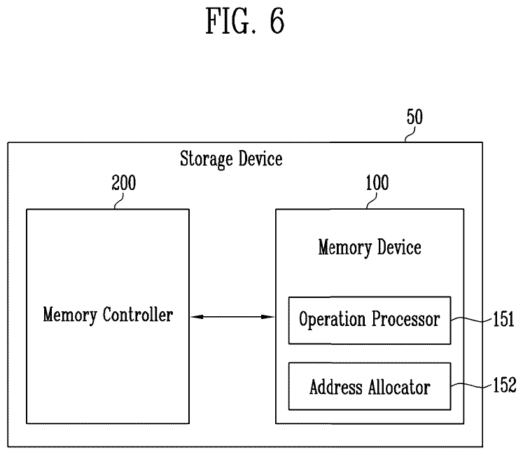

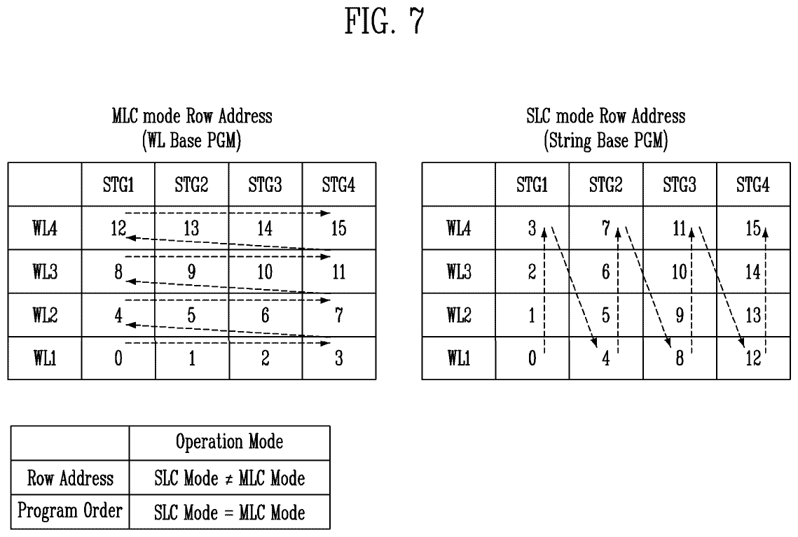

In an embodiment, the memory controller 200 may control the memory device 100 to perform a program operation on the memory block on a string group basis in the SLC mode, and perform the program operation on the memory block on a word line basis in the MLC mode. The memory controller 200 may set the program order based on row addresses differently in the SLC mode and the MLC mode, respectively. The memory controller 200 may provide a command indicating the program operation mode and the row addresses of the memory block depending on the set program order to the memory device 100. Here, the row addresses of the memory block may be equally allocated by the memory device 100 in the SLC mode and the MLC mode. Detailed description thereof will be made later with reference to FIGS. 6 and 7.

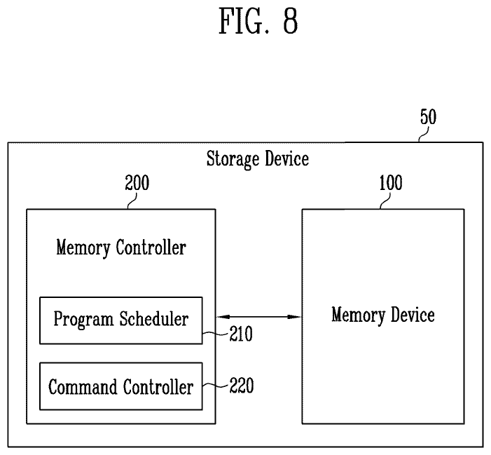

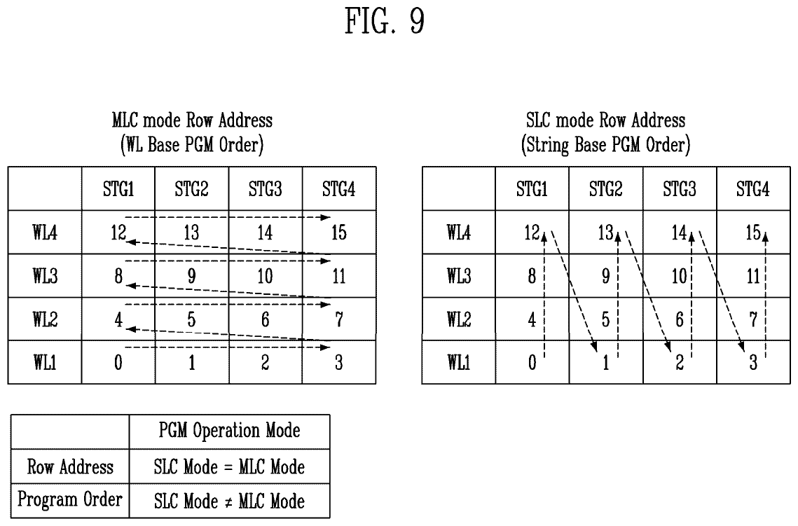

In an embodiment, the memory device 100 may independently perform a program operation on the memory block on a string group basis in the SLC mode and perform a program operation on the memory block on a word line basis in the MLC mode. The memory device 100 may set the program operation mode to the SLC mode or the MLC mode in response to the command received from the memory controller 200. The memory device 100 may allocate the row addresses of the memory block differently in the SLC mode and the MLC mode, respectively. Here, the program order based on the row addresses of the memory block may be equally set by the memory controller 200. Detailed description thereof will be made later with reference to FIGS. 8 and 9.

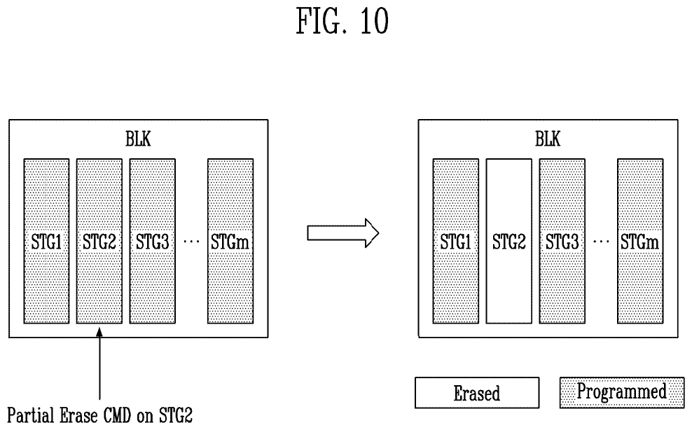

In an embodiment, the memory controller 200 may provide a partial erase command for erasing a string group selected from among the plurality of string groups to the memory device 100. The memory device 100 may erase the selected string group in response to the partial erase command. Detailed description thereof will be made later with reference to FIG. 10.

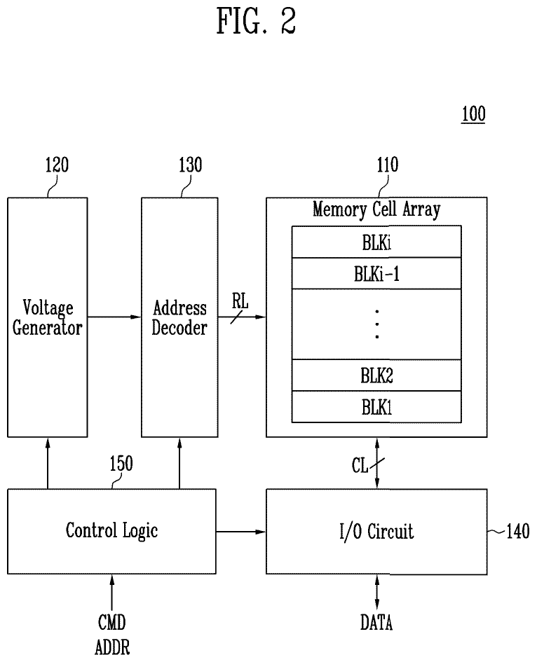

FIG. 2 is a diagram illustrating the memory device of FIG. 1.

Referring to FIG. 2, the memory device 100 may include a memory cell array 110, a voltage generator 120, an address decoder 130, an input/output (I/O) circuit 140, and a control logic 150.

The memory cell array 110 may include a plurality of memory blocks BLK1 to BLKi. The plurality of memory blocks BLK1 to BLKi are connected to the address decoder 130 through row lines RL. The plurality of memory blocks BLK1 to BLKi may be connected to the input/output circuit 140 through column lines CL. In an embodiment, the row lines RL may include word lines, source select lines, and drain select lines. In an embodiment, the column lines CL may include bit lines.

Each of the memory blocks BLK1 to BLKi may include a plurality of memory cells. In an embodiment, the plurality of memory cells may be nonvolatile memory cells. Memory cells connected to the same word line, among the plurality of memory cells, may be defined as one page. That is, each of the memory blocks BLK1 to BLKi may include a plurality of pages.

The memory cells included in the memory cell array 110 may include a single-level cell (SLC) in which 1 data bit is stored, or a multi-level cell (MLC) in which 2 or more data bits are stored. The multi-level cell may include a triple-level cell (TLC) capable of storing three data bits or a quad-level cell (QLC) capable of storing four data bits.

In an embodiment, the voltage generator 120, the address decoder 130, and the input/output circuit 140 may be collectively referred to as a peripheral circuit. The peripheral circuit may drive the memory cell array 110 under the control of the control logic 150. The peripheral circuit may drive the memory cell array 110 to perform a write operation (program operation), a read operation, and an erase operation.

The voltage generator 120 may generate a plurality of operating voltages using an external supply voltage provided to the memory device 100. The voltage generator 120 may be operated under the control of the control logic 150. In an embodiment, the voltage generator 120 may generate an internal supply voltage by regulating the external supply voltage. The internal supply voltage generated by the voltage generator 120 may be used as an operating voltage for the memory device 100.

In an embodiment, the voltage generator 120 may generate a plurality of operating voltages using the external supply voltage or the internal supply voltage. The voltage generator 120 may generate various voltages required by the memory device 100. For example, the voltage generator 120 may generate a plurality of erase voltages, a plurality of program voltages, a plurality of pass voltages, a plurality of select read voltages, and a plurality of unselect read voltages.

The voltage generator 120 may include a plurality of pumping capacitors for receiving the internal supply voltage to generate a plurality of operating voltages having various voltage levels, and may generate a plurality of operating voltages by selectively enabling the plurality of pumping capacitors under the control of the control logic 150.

The plurality of generated operating voltages may be supplied to the memory cell array 110 by the address decoder 130.

The address decoder 130 is connected to the memory cell array 110 through the row lines RL. The address decoder 130 may be operated in response to control of the control logic 150. The address decoder 130 may receive addresses ADDR from the control logic 150. The address decoder 130 may decode a block address among the received addresses ADDR. The address decoder 130 may select at least one of the memory blocks BLK1 to BLKi according to the decoded block address. The address decoder 130 may decode a row address among the received addresses ADDR. The address decoder 130 may select at least one of word lines of the selected memory block according to the decoded row address. In an embodiment, the address decoder 130 may decode a column address among the received addresses ADDR. The address decoder 130 may connect the input/output circuit 140 to the memory cell array 110 according to the decoded column address.

In an embodiment, the address decoder 130 may include components, such as a row decoder, a column decoder, and an address buffer.

The input/output circuit 140 may include a plurality of page buffers (not illustrated). The plurality of page buffers may be connected to the memory cell array 110 through the bit lines. During a write operation (program operation), data (DATA) may be stored in the selected memory cells depending on the data stored in the plurality of page buffers. During a read operation, data stored in the selected memory cells may be measured through the bit lines, and the measured data may be stored in the page buffers.

The control logic 150 may control the address decoder 130, the voltage generator 120, and the input/output circuit 140. The control logic 150 may be operated in response to a command CMD transmitted from an external device. The control logic 150 may control the peripheral circuit by generating control signals in response to the command CMD and the addresses ADDR.

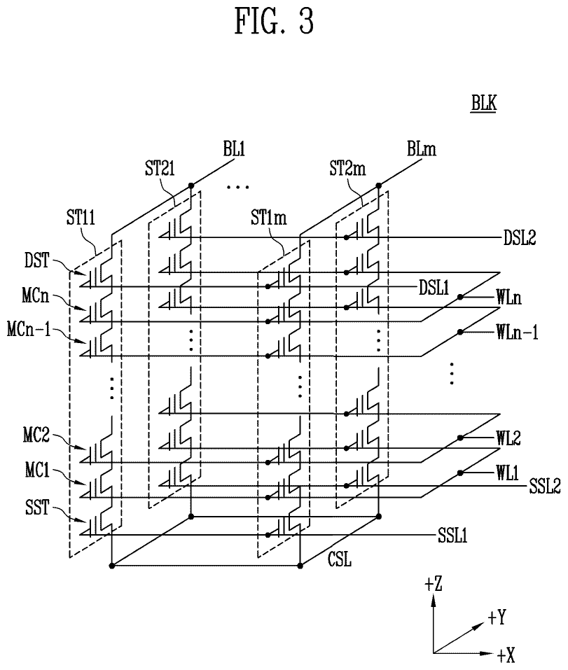

FIG. 3 is a diagram illustrating the structure of the memory block of FIG. 2.

Referring to FIG. 3, the memory block BLK may include a plurality of strings ST11 to ST1m and ST21 to ST2m. Each of the plurality of strings ST11 to ST1m and ST21 to ST2m may extend along a +Z direction. Each of the strings ST11 to ST1m and ST21 to ST2m includes at least one source select transistor SST, first to n-th memory cells MC1 to MCn, and at least one drain select transistor DST, which are stacked on a substrate (not illustrated) under the memory block BLK.

In an embodiment, one memory block may include a plurality of sub-blocks. One sub-block may include strings arranged in an ‘I’-shape in one column.

The source select transistor SST in each string is connected between a common source line CSL and the memory cells MC1 to MCn. The source select transistors of strings arranged in the same row are connected to the same source select line. The source select transistors of the strings ST11 to ST1m arranged in a first row may be connected to a first source select line SSL1. The source select transistors of the strings ST21 to ST2m arranged in a second row may be connected to a second source select line SSL2. In other embodiments, the source select transistors of the strings ST11 to ST1m and ST21 to ST2m may be connected in common to a single source select line.

The first to n-th memory cells MC1 to MCn in each string are connected in series between the source select transistor SST and the drain select transistor DST. Gates of the first to n-th memory cells MC1 to MCn are connected to first to n-th word lines WL1 to WLn, respectively.

The drain select transistor DST in each string is connected between the corresponding bit line and the memory cells MC1 to MCn. The drain select transistors of strings arranged in the row direction may be connected to drain select lines extending in the row direction. The drain select transistors of the strings ST11 to ST1m in the first row are connected to a first drain select line DSL1. The drain select transistors of the strings ST21 to ST2m in the second row are connected to a second drain select line DSL2.

In other embodiments, instead of the first to m-th bit lines BL1 to BLm, even bit lines and odd bit lines may be provided. Further, even-numbered strings among the strings ST11 to ST1m or ST21 to ST2m arranged in the row direction may be connected to even bit lines, respectively, and odd-numbered strings among the strings ST11 to ST1m or ST21 to ST2m arranged in the row direction may be connected to odd bit lines, respectively.

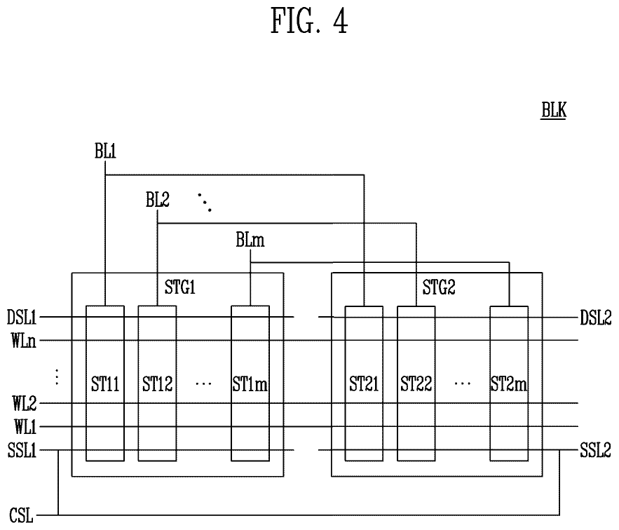

FIG. 4 is a diagram illustrating a partial structure of the memory block of FIG. 3.

Referring to FIG. 4, the memory block BLK may include a plurality of string groups. Among the plurality of string groups, a first string group STG1 may include first strings ST11 to ST1m which share a first drain select line DSL1. Each of the first strings ST11 to ST1m may include a drain select transistor connected to the first drain select line DSL1, memory cells connected to a plurality of word lines WL1 to WLn, and a source select transistor connected to a first source select line SSL1.

A second string group STG2 may include second strings ST21 to ST2m which share a second drain select line DSL2. Each of the second strings ST21 to ST2m may include a drain select transistor connected to the second drain select line DSL2, memory cells connected to the plurality of word lines WL1 to WLn, and a source select transistor connected to a second source select line SSL2.

The first source select line SSL1 and the second source select line SSL2 may be connected to a common source line CSL. The first string ST11 among the first strings ST11 to ST1m and the first string ST21 among the second strings ST21 to ST2m may be connected to a first bit line BL1. The second string ST12 among the first strings ST11 to ST1m and the second string ST22 among the second strings ST21 to ST2m may be connected to a second bit line BL2. In the same manner, the m-th string ST1m among the first strings ST11 to ST1m and the m-th string ST2m among the second strings ST21 to ST2m may be connected to an m-th bit line BLm.

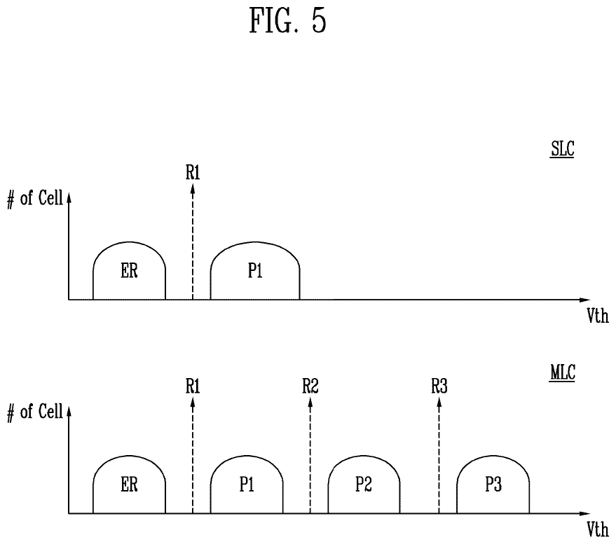

FIG. 5 is a diagram illustrating a threshold voltage distribution depending on the number of data bits stored in each memory cell.

Referring to FIG. 5, each memory cell may be a single-level cell (SLC) in which 1 data bit is stored. The threshold voltage distribution of the single-level cell may have one of an erase state ER and a first program state P1, and may be read by a first read voltage R1.

In FIG. 5, the memory cell may be a multi-level cell (MLC) in which 2 or more data bits are stored. The multi-level cell is assumed to store two data bits. In an embodiment, the multi-level cell may be a triple-level cell in which three data bits are stored, or a quad-level cell in which four data bits are stored. The threshold voltage distribution of the multi-level cell may have one of an erase state ER and first to third program states P1, P2, and P3, and may be read by first to third read voltages R1, R2, and R3.

The single-level cell may have a read voltage distribution margin wider than that of the multi-level cell. Therefore, in an embodiment, the single-level cell may have a program operation speed and a read operation speed that are faster than those of the multi-level cell and have a lifespan longer than that of the multi-level cell, and may be less affected by memory cell degradation or read disturbance than the multi-level cell.

FIG. 6 is a diagram illustrating the storage device of FIG. 1 according to an embodiment.

Referring to FIG. 6, the memory device 100 may include an operation processor 151 and an address allocator 152. The operation processor 151 and the address allocator 152 may be components included in the control logic 150, described above with reference to FIG. 2.

The memory device 100 may include a memory block including a plurality of string groups connected to a plurality of word lines. Row addresses of the memory block may be determined depending on the positions of the plurality of word lines and the positions of the plurality of string groups. The structure of the memory block may be described with reference to FIG. 4.

The operation processor 151 may set the program operation mode of the memory block to one of a single-level cell (SLC) mode and a multi-level cell (MLC) mode in response to a command received from the memory controller 200. The memory block may store 1 bit per unit memory cell in the SLC mode, and may store 2 or more bits per unit memory cell in the MLC mode.

The operation processor 151 may erase a string group selected from among the plurality of string groups included in the memory block in response to a partial erase command received from the memory controller 200.

The address allocator 152 may allocate the row addresses of the memory block differently depending on the program operation mode. The address allocator 152 may allocate the row addresses of the memory block differently in the SLC mode and the MLC mode, respectively. The address allocator 152 may allocate row addresses so that the program operation is performed on a string group basis in the SLC mode and so that the program operation is performed on a word line basis in the MLC mode. The program order based on the row addresses may be equally set by the memory controller both in the SLC mode and in the MLC mode.

FIG. 7 is a diagram illustrating allocation of row addresses of a memory block by the memory device of FIG. 6 depending on a program operation mode.

Referring to FIG. 7, the memory block may include a plurality of string groups connected to a plurality of word lines. The row addresses may be determined depending on the positions of the plurality of word lines and the positions of the plurality of string groups.

In FIG. 7, the memory block may include first to fourth string groups STG1 to STG4 connected to first to fourth word lines WL1 to WL4.

As described above with reference to FIG. 6, the memory device may allocate the row addresses of the memory block differently in the SLC mode and the MLC mode, respectively. For example, row addresses (i.e., 0, 1, 2, and 3 in FIG. 7 for the MLC mode) allocated based on a word line basis in the MLC mode are sequentially assigned to locations where string groups (i.e., STG1, STG2, STG3, and STG4 in FIG. 7 for the MLC mode) intersect with a target word line (i.e., WL1 in FIG. 7 for the MLC mode), and the row addresses (i.e., 0, 1, 2, and 3 in FIG. 7 for the SLC mode) allocated based on a string group basis in the SLC mode are sequentially assigned to locations where word lines (i.e., WL1, WL2, WL3, and WL4 in FIG. 7 for the SLC mode) intersect with a target string group (i.e., STG1 in FIG. 7 for the SLC mode). In an embodiment, a target word line may be a single word line selected from a plurality of word lines, and a target string group may be a single string group selected from a plurality of string groups.

For example, the memory device may allocate row addresses from row address ‘0’ to row address ‘3’ in the order of the first word line WL1 to the fourth word line WL4 with respect to the first string group STG1 so that the program operation is performed on a string group basis in the SLC mode. Next, the memory device may allocate row addresses from row address ‘4’ to row address ‘7’ in the order of the first word line WL1 to the fourth word line WL4 with respect to the second string group STG2. Similarly, the memory device may allocate row addresses from row address ‘8’ to row address ‘15’ with respect to the third string group STG3 and the fourth string group STG4. For example, referring to FIG. 7 and the SLC mode, the memory device may allocate a first set of row addresses (i.e., 0, 1, 2, and 3), in a sequential order, depending on the number of word lines intersecting with a target string group (i.e., a first string group STG1 selected from a plurality of string groups STG1 to STG4). Then allocate a second set of row addresses (i.e., 4, 5, 6, and 7), in a sequential order, for a target string group (i.e., second string group STG2 selected from a plurality of string groups STG1 to STG4) dependent on the number of word lines for the first string group STG1 that now intersect with the target string group (i.e., second string group STG2). In an embodiment, the first set of row addresses (i.e., ‘0’ to ‘3’) are sequentially and consecutively followed by the second set of row addresses (i.e., ‘4’ to ‘7’). The first set of row addresses having addresses that are sequential and consecutive addresses within a target string group (i.e., first string group STG1), the number of addresses depending on the number of word lines that intersect with the target string group (i.e., first string group STG1 selected from a plurality of string groups STG1 to STG4). For example, the first set of row addresses may include the first row address ‘0’ being allocated for the first word line WL1 that intersects with the first string group STG1, the second row address ‘1’ being allocated for the second word line WL2 that intersects with the first string group STG1, the third row address ‘2’ being allocated for the third word line WL3 that intersects with the first string group STG1, and fourth row address ‘3’ being allocated for the fourth word line WL4 that intersects with the first string group STG1. The second set of row addresses having addresses that are sequential and consecutive addresses within a second string group STG2, the number of addresses depending on the number of word lines that intersect with the second string group STG2. For example, the second set of row addresses may include the fifth row address ‘4’ being allocated for the first word line WL1 that intersects with the second string group STG2, the sixth row address ‘5’ being allocated for the second word line WL2 that intersects with the second string group STG2, the seventh row address ‘6’ being allocated for the third word line WL3 that intersects with the second string group STG2, and eight row address ‘7’ being allocated for the fourth word line WL4 that intersects with the second string group STG2. The program order for the string group basis starting with the first row address ‘0’ and sequentially and consecutively flowing with the other row addresses (i.e., ‘1’ to ‘14’) and concluding with the last row address or sixteenth row address ‘15’.

For example, the memory device may allocate row addresses from row address ‘0’ to row address ‘3’ in the order of the first string group STG1 to the fourth string group STG4 with respect to the first word line WL1 so that the program operation is performed on a word line basis in the MLC mode. Next, the memory device may allocate row addresses from row address ‘4’ to row address ‘7’ in the order of the first string group STG1 to fourth string group STG4 with respect to the second word line WL2. In a similar manner, the memory device may allocate row addresses from row address ‘8’ to row address ‘15’ with respect to the third word line WL3 and the fourth word line WL4. For example, referring to FIG. 7 and the MLC mode, the memory device may allocate a first set of row addresses (i.e., 0, 1, 2, and 3) in a sequential order depending on the number of string groups intersecting with a target word line (i.e., a first word line WL1 selected from a plurality of word lines WL1 to WL4). Then allocate a second set of row addresses (i.e., 4, 5, 6, and 7) in a sequential order, for a target word line (i.e., a second word line WL2 selected from a plurality of word lines WL1 to WL4) dependent on the number of string groups that intersected for the first word line WL1 that now also intersects with the second word line WL2. The first set of row addresses (i.e., ‘0’ to ‘3’) sequentially and consecutively followed by the second set of row addresses (i.e., ‘4’ to ‘7’). The first set of row addresses having addresses that are sequential and consecutive addresses within a first word line WL1, the number of addresses depending on the number of string groups (i.e., string groups STG1 to STG4) that intersect with the first word line WL1. For example, the first set of row addresses may include the first row address ‘0’ being allocated for the first word line WL1 that intersects with the first string group STG1, the second row address ‘1’ being allocated for the first word line WL1 that intersects with the second string group STG2, the third row address ‘2’ being allocated for the first word line WL1 that intersects with the third string group STG3, and fourth row address ‘3’ being allocated for the first word line WL1 that intersects with the fourth string group STG4. The second set of row addresses having addresses that are sequential and consecutive addresses within a second word line WL2, the number of addresses depending on the number of string groups that intersect with the second word line. For example, the second set of row addresses may include the fifth row address ‘4’ being allocated for the second word line WL2 that intersects with the first string group STG1, the sixth row address ‘5’ being allocated for the second word line WL2 that intersects with the second string group STG2, the seventh row address ‘6’ being allocated for the second word line WL2 that intersects with the third string group STG3, and eight row address ‘7’ being allocated for the second word line WL2 that intersects with the fourth string group STG4. The program order for the word line basis starting with the first row address ‘0’ and sequentially and consecutively flowing with the other row addresses (i.e., ‘1’ to ‘14’) and concluding with the last row address or sixteenth row address ‘15’. Thus, the row addresses assigned on word line basis in the MLC mode include row addresses that do not intersect with the same word line and string group locations as for the row addresses assigned on the string group basis in the SLC mode. For example, row address ‘1’ assigned based on the word line basis is located at the intersection of the first word line WL1 and the second string group STG2 but when the row address ‘1’ is assigned based on the string group basis the row address ‘1’ is located at a different location where the second word line WL2 intersects with the string group STG1. This can, for example, be seen in FIG. 7.

Whereas the program order based on the row addresses may be equally set by the memory controller both in the SLC mode and in the MLC mode. The program order based on row addresses may be set such that, both in the SLC mode and in the MLC mode, row addresses are sequentially increased from row address ‘0’ to row address ‘15’. For example, as shown in FIG. 7, the arrows indicating the program order for both the SLC mode and MLC mode, the program order for the row addresses ‘0’ to ‘15’ are sequentially performed by increasing from row address ‘0’ to row address ‘15’ in both the SLC mode and the MLC mode.

FIG. 8 is a diagram illustrating the storage device of FIG. 1 according to an embodiment.

Referring to FIG. 8, the memory device 100 may include a memory block including a plurality of string groups connected to a plurality of word lines. The structure of the memory block may be described with reference to FIG. 4. Row addresses of the memory block may be determined depending on the positions of the plurality of word lines and the positions of the plurality of string groups. Here, the row addresses of the memory block may be equally allocated both in an SLC mode and in an MLC mode by the memory device 100.

The memory controller 200 may include a program scheduler 210 and a command controller 220.

The program scheduler 210 may set the program operation mode of the memory block to one of a single-level cell (SLC) mode and a multi-level cell (MLC) mode. The program scheduler 210 may set the program order based on the row addresses of the memory block differently depending on the program operation mode. The program scheduler 210 may set the program order based on the row addresses differently in the SLC mode and the MLC mode, respectively. The program scheduler 210 may set the program order so that the program operation is performed on a string group basis in the SLC mode and so that the program operation is performed on a word line basis in the MLC mode.

The command controller 220 may provide a command indicating the program operation mode to the memory device 100, and may provide the row addresses of the memory block to the memory device 100 depending on the program order. The command controller 220 may provide a partial erase command for erasing a string group selected from among the plurality of string groups included in the memory block to the memory device 100.

FIG. 9 is a diagram illustrating the setting of a program order based on the row addresses of a memory block by the memory controller of FIG. 8 depending on a program operation mode.

Referring to FIG. 9, the memory block may include first to fourth string groups STG1 to STG4 connected to first to fourth word lines WL1 to WL4.

The row addresses of the memory block may be equally allocated by the memory device both in an SLC mode and in an MLC mode. For example, row addresses from row address 0 to row address 3 may be allocated in the order of the first string group STG1 to the fourth string group STG4 with respect to the first word line WL1. Row addresses from row address 4 to row address 7 may be allocated in the order of the first string group STG1 to the fourth string group STG4 with respect to the second word line WL2. In a similar manner, row addresses from row address 8 to row address 15 may be allocated with respect to the third word line WL3 and the fourth word line WL4.

As described above with reference to FIG. 8, the memory controller may set the program order based on the row addresses differently in the SLC mode and the MLC mode, respectively. The memory controller may set the program order so that a program operation is performed on the memory block on a string group basis in the SLC mode and so that a program operation is performed on a word line basis in the MLC mode.

For example, the memory controller may set the program order based on row addresses so that the row addresses proceed to 0, 4, 8, and 12 with respect to the first string group STG1 in order to perform the program operation on a string group basis in the SLC mode. The memory controller may set the next program order so that the row addresses proceed to 1, 5, 9, and 13 with respect to the second string STG2. In a similar manner, the memory controller may set the program order so that the row addresses proceed to 2, 6, 10, and 14 with respect to the third string group STG3, and the row addresses proceed to 3, 7, 11 and 15 with respect to the fourth string group STG4.

For example, the memory controller may set the program order based on row addresses so that the row addresses sequentially increase from row address 0 to row address 15 in order to perform the program operation on a word line basis in the MLC mode.

FIG. 10 is a diagram illustrating a partial erase operation on a string group.

Referring to FIG. 10, the memory block BLK may include a plurality of string groups. The memory device may perform an erase operation on a string group selected from among the plurality of string groups in response to a partial erase command received from the memory controller to erase the selected string group.

In FIG. 10, the memory device may perform an erase operation on a second string group STG2 selected from among first to m-th string groups STG1 to STGm in response to a partial erase command for erasing the second string group STG2.

In accordance with an embodiment described with reference to FIG. 10, an erase operation may be performed on a portion of the memory block other than the entire memory block. Furthermore, in an embodiment, the influence of gate-induced drain leakage (GIDL) current on adjacent memory cells may be reduced compared to a partial erase operation on a word line basis by performing the erase operation on a string group basis rather than a word line basis.

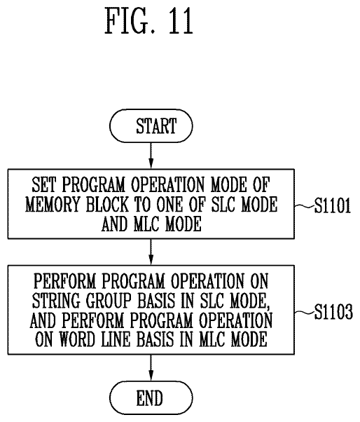

FIG. 11 is a flowchart illustrating a method of operating a storage device according to an embodiment.

Referring to FIG. 11, at S1101, the storage device may set the program operation mode of a memory block to one of an SLC mode and an MLC mode.

At S1103, the storage device may perform a program operation on a string group basis in the SLC mode, and may perform a program operation on a word line basis in the MLC mode.

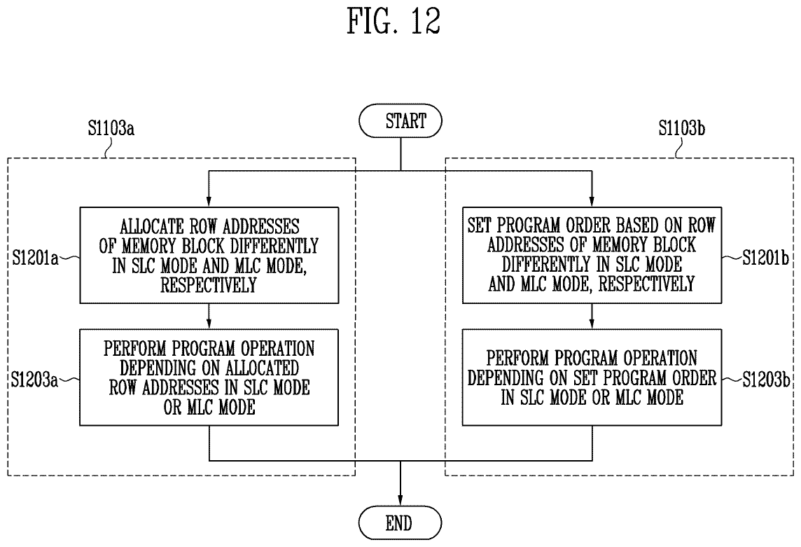

FIG. 12 is a flowchart illustrating in detail the method of operating the storage device illustrated in FIG. 11.

Referring to FIG. 12, S1103a may be an embodiment of S1103, and may include S1201a and S1203a.

At S1201a, the storage device may allocate the row addresses of the memory block differently in the SLC mode and the MLC mode, respectively. For example, in the SLC mode and the MLC mode, the memory controller may equally set the program order based on row addresses, and the memory device may differently set the row addresses of the memory block.

At S1203a, the storage device may perform a program operation depending on the allocated row addresses in the SLC mode or the MLC mode.

S1103b may be an embodiment of S1103, and may include S1201b and S1203b.

At S1201b, the storage device may set the program order based on the row addresses of the memory block differently in the SLC mode and the MLC mode, respectively. For example, in the SLC mode and the MLC mode, the memory controller may differently set the program order based on row addresses, and the memory device may equally set the row addresses of the memory block.

At S1203b, the storage device may perform a program operation depending on the set program order in the SLC mode or the MLC mode.

According to various embodiments of the present disclosure, there are provided a storage device and a method of operating the storage device, which efficiently manage a storage space

What is claimed is:

1. A memory device, comprising:
a memory block including a plurality of string groups connected to a plurality of word lines;
an operation processor configured to set a program operation mode of the memory block to one of a single-level cell (SLC) mode and a multi-level cell (MLC) mode in response to a command received externally from the memory device; and
an address allocator configured to allocate a row address of the memory block differently depending on the program operation mode.

2. The memory device according to claim 1, wherein the memory block stores 1 bit per unit memory cell in the SLC mode, and stores 2 or more bits per unit memory cell in the MLC mode.

3. The memory device according to claim 1, wherein the address allocator allocates the row address so that the program operation is performed on a string group basis in the SLC mode and is performed on a word line basis in the MLC mode.

4. The memory device according to claim 3, wherein the address allocator allocates the row addresses based on the word line basis in the MLC mode by sequentially assigning the row addresses, respectively, to locations where string groups intersect with a target word line.

5. The memory device according to claim 3, wherein the address allocator allocates the row addresses based on the string group basis in the SLC mode by sequentially assigning the row addresses, respectively, to locations where word lines intersect with a target string group.

6. The memory device according to claim 1, wherein the row address is determined depending on positions of the plurality of word lines and positions of the plurality of string groups.

7. The memory device according to claim 6, wherein the address allocator allocates a row address of the memory block differently in the SLC mode and the MLC mode, respectively.

8. The memory device according to claim 1, wherein the program order based on the row address is equally set by the memory controller in the SLC mode and the MLC mode, respectively.

9. The memory device according to claim 1, wherein:
a first string group among the plurality of string groups comprises first strings sharing a first drain select line,
each of the first strings comprises a drain select transistor connected to the first drain select line, memory cells connected to the plurality of word lines, and a source select transistor connected to a first source select line,
a second string group among the plurality of string groups comprises second strings sharing a second drain select line, and
each of the second strings comprises a drain select transistor connected to the second drain select line, memory cells connected to the plurality of word lines, and a source select transistor connected to a second source select line.

10. The memory device according to claim 1, wherein the operation processor erases a string group selected from among the plurality of string groups in response to a partial erase command received from the memory controller.

11. A memory controller for controlling a memory device, the memory device including a memory block including a plurality of string groups connected to a plurality of word lines, the memory controller comprising:
a program scheduler configured to set a program operation mode of the memory block to one of a single-level cell (SLC) mode and a multi-level cell (MLC) mode and set a program order based on a row address of the memory block differently depending on the program operation mode; and
a command controller configured to provide a command indicating the program operation mode and the row address of the memory block depending on the program order to the memory device.

12. The memory controller according to claim 11, wherein the memory block stores 1 bit per unit memory cell in the SLC mode, and stores 2 or more bits per unit memory cell in the MLC mode.

13. The memory controller according to claim 11, wherein the program scheduler sets the program order so that the program operation is performed on a string group basis in the SLC mode and is performed on a word line basis in the MLC mode.

14. The memory controller according to claim 13, the program scheduler sets the program order so that the program operation is performed on the string group basis in the SLC mode by sequentially assigning row addresses, respectively, to locations where word lines interest with a target string group.

15. The memory controller according to claim 13, wherein the program scheduler sets the program order so that the program operation is performed on the word line basis in the MLC mode by sequentially assigning row addresses, respectively, to locations where string groups intersect with a target word line.

16. The memory controller according to claim 11, wherein the program scheduler sets the program order based on the row address differently in the SLC mode and the MLC mode, respectively.

17. The memory controller according to claim 11, wherein the row address is determined depending on positions of the plurality of word lines and positions of the plurality of string groups.

18. The memory controller according to claim 17, wherein the row address of the memory block is equally allocated by the memory device in the SLC mode and the MLC mode, respectively.

19. The memory controller according to claim 11, wherein:
a first string group among the plurality of string groups comprises first strings sharing a first drain select line,
each of the first strings comprises a drain select transistor connected to the first drain select line, memory cells connected to the plurality of word lines, and a source select transistor connected to a first source select line,
a second string group among the plurality of string groups comprises second strings sharing a second drain select line, and
each of the second strings comprises a drain select transistor connected to the second drain select line, memory cells connected to the plurality of word lines, and a source select transistor connected to a second source select line.

20. The memory controller according to claim 11, wherein the command controller provides a partial erase command for erasing a string group selected from among the plurality of string groups to the memory device.

21. A method of operating a storage device, the storage device including a memory controller and a memory device including a memory block, the method comprising:
setting a program operation mode of the memory block to a single-level cell (SLC) mode in which 1 bit is stored per unit memory cell or a multi-level cell (MLC) mode in which 2 or more bits are stored per unit memory cell; and
performing a program operation on the memory block on a string group basis in the SLC mode and performing the program operation on a word line basis in the MLC mode,
wherein the memory block comprises a plurality of string groups connected to a plurality of word lines, and
wherein a row address of the memory block is determined depending on positions of the plurality of word lines and positions of the plurality of string groups.

22. The method according to claim 21, wherein performing the program operation comprises:
allocating the row address of the memory block differently depending on whether the program operation mode is the SLC mode or the MLC mode; and
performing the program operation depending on the allocated row address.

23. The method according to claim 21, wherein performing the program operation comprises:
setting a program order based on the row address of the memory block differently depending on whether the program operation mode is the SLC mode or the MLC mode; and
performing the program operation depending on the set program order.

24. The method according to claim 21, further comprising:
performing a partial erase operation of erasing a string group selected from among the plurality of string groups.
